(19) United States
(12) Patent Application Publication
(10) Pub. No.: US 2005/0194622 A1
(43) Pub. Date: Sep. 8, 2005

(54) Nonvolatile capacitor of a semiconductor device, semiconductor memory device including the capacitor, and method of operating the same

(75) Inventors: Jung-hyun Lee, Yongin-si (KR); Sung-ho Park, Seoul (KR); Myoung-jae Lee, Suwon-si (KR); Young-soo Park, Suwon-si (KR)

Correspondence Address: Eugene M. Lee;LEE & STERBA, PC, Suite 2000, 1101 Wilson Boulevard, Arlington, VA, 22209, US

(73) Assignee: Samsung Electronics Co., Ltd.

(21) Appl. No.: 11/013,923

(22) Filed: Dec. 17, 2004

(30) Foreign Application Priority Data
Dec. 17, 2003 (KR) 2003-92614

(51) Int. Cl. H01L 21/8242; H01L 21/20; H01L 31/062; H01L 29/94; H01L 29/76; H01L 31/113; H01L 31/119; H01L 27/108

(52) U.S. Cl. 257/288; 257/310; 438/240

(57) ABSTRACT

In a capacitor of a semiconductor device, a semiconductor memory device including the capacitor, and a method of operating the semiconductor memory device, the capacitor includes a lower electrode, a dielectric layer stacked on the lower electrode, the dielectric layer including a phase-transition layer capable of exhibiting two different resistance characteristics depending on whether an insulating property thereof has been changed, and an upper electrode stacked on the dielectric layer.

### BACKGROUND OF THE INVENTION

1. Field of the Invention

The present invention relates to a capacitor and a semiconductor memory device including the same. More particularly, the present invention relates to a nonvolatile capacitor of a semiconductor device, a semiconductor memory device including the capacitor, and a method of operating the memory device.

2. Description of the Related Art

A semiconductor memory device basically includes a transistor and a capacitor. In recent years, various storage media, e.g., a magnetic tunneling junction (MTJ) cell included in a magnetic memory device, have been developed as substitutes for capacitors.

Preferably, a semiconductor memory device has high integration, high operation speed, and superior nonvolatility sufficient to avoid loss of data stored therein even after power is switched off. On one hand, among widely used semiconductor memory devices, a dynamic random access memory (DRAM) has advantages of a high integration and a high operation speed, but does not have nonvolatility. Accordingly, a DRAM loses all data after power is interrupted. On the other hand, a flash memory is nonvolatile, but has a lower integration and a lower operation speed than the DRAM.

### SUMMARY OF THE INVENTION

The present invention is therefore directed to a nonvolatile capacitor of a semiconductor device, a semiconductor memory device including the capacitor, and a method of operating the memory device, which substantially overcome one or more of the problems due to the limitations and disadvantages of the related art.

It is a feature of an embodiment of the present invention to provide a nonvolatile capacitor and a nonvolatile semiconductor memory device including the capacitor, which has a high operation speed of a dynamic random access memory (DRAM) and a nonvolatililty of a flash memory device.

It is another feature of an embodiment of the present invention to provide a method of operating the semiconductor memory device.

At least one of the above and other features and advantages of the present invention may be realized by providing a capacitor of a semiconductor device, the capacitor including a lower electrode, a dielectric layer stacked on the lower electrode, the dielectric layer including a phase-transition layer capable of exhibiting two different resistance characteristics depending on whether an insulating property thereof has been changed, and an upper electrode stacked on the dielectric layer.

At least one of the above and other features and advantages of the present invention may be realized by providing a semiconductor memory device including a transistor and a capacitor, the capacitor including a lower electrode, a dielectric layer stacked on the lower electrode, the dielectric layer including a phase-transition layer capable of displaying two different resistance characteristics depending on whether an insulating property thereof has been changed, and an upper electrode stacked on the dielectric layer.

In the capacitor, the dielectric layer may include a first insulating layer stacked on the lower electrode, the phase-transition layer stacked on the first insulating layer, and a second insulating layer stacked on the phase-transition layer.

Either of the first and second insulating layers may be a dielectric layer having a dielectric constant greater than a dielectric constant of the phase-transition layer. The dielectric layer of either the first or second insulating layers may be one selected from the group consisting of a silicon oxide layer, a tantalum oxide layer and an aluminum oxide layer.

The phase-transition layer may be a dielectric layer capable of exhibiting two different resistance characteristics according to an applied voltage after at least one component of the phase-transition layer is separated by electrons injected into the phase-transition layer. The phase-transition layer may be a niobium oxide layer.

The phase-transition layer may be a dielectric layer capable of exhibiting two different resistance characteristics according to an applied voltage after at least one component of the phase-transition layer is separated by light applied to the capacitor.

A thickness ratio of the first insulating layer, the phase-transition layer, and the second insulating layer may be 5:6:5.

At least one of the layers constituting the dielectric layer may be a ferroelectric layer.

The capacitor may be a cylinder-type stacked capacitor.

At least one of the above and other features and advantages of the present invention may be realized by providing a method of operating a semiconductor memory device including a transistor and a capacitor, wherein the capacitor includes a lower electrode, a dielectric layer including a phase-transition layer capable of exhibiting two different resistance characteristics depending on whether an insulating property thereof has been changed, and an upper electrode, the method including changing the insulating property of the phase-transition layer and applying a write voltage to the capacitor while leaving the transistor turned on.

Changing the insulating property of the phase-transition layer may include injecting electrons into the phase-transition layer. Injecting electrons into the phase-transition layer may include applying a voltage to the capacitor.

Changing the insulating property of the phase-transition layer may include applying light to the capacitor. The light may be ultraviolet light.

At least one of the above and other features and advantages of the present invention may be realized by providing a method of operating a semiconductor memory device including a transistor and a capacitor, wherein the capacitor includes a lower electrode, a dielectric layer including a phase-transition layer capable of exhibiting two different resistance characteristics depending on whether an insulating property thereof has been changed, and an upper electrode, the method including measuring a current by applying a read voltage to the capacitor while leaving the transistor turned on and comparing the measured current value with a reference value.

A semiconductor memory device according to an embodiment of the present invention has advantages of both DRAM and flash memory in that the semiconductor device according to an embodiment of the present invention is as fast as a DRAM and is as nonvolatile as a flash memory.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a cross-sectional view of a nonvolatile capacitor of a semiconductor device according to an embodiment of the present invention;

FIG. 2 is a graph of current versus voltage illustrating operational characteristics of the capacitor of FIG. 1;

FIG. 3 is a graph of current versus a number of times an endurance test is performed illustrating results of the endurance test of the capacitor of FIG. 1;

FIG. 4 illustrates a cross-sectional view of a semiconductor memory device according to an embodiment of the present invention, the semiconductor memory device including the capacitor of FIG. 1; and

FIG. 5 is a plot illustrating various phases of a niobium oxide layer according to a content of oxygen.

### DETAILED DESCRIPTION OF THE INVENTION

Korean Patent Application No. 2003-92614, filed on Dec. 17, 2003, in the Korean Intellectual Property Office, and entitled: “Nonvolatile Capacitor of a Semiconductor Device, Semiconductor Memory Device Comprising the Capacitor, and Method of Operating the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Like reference numerals refer to like elements throughout.

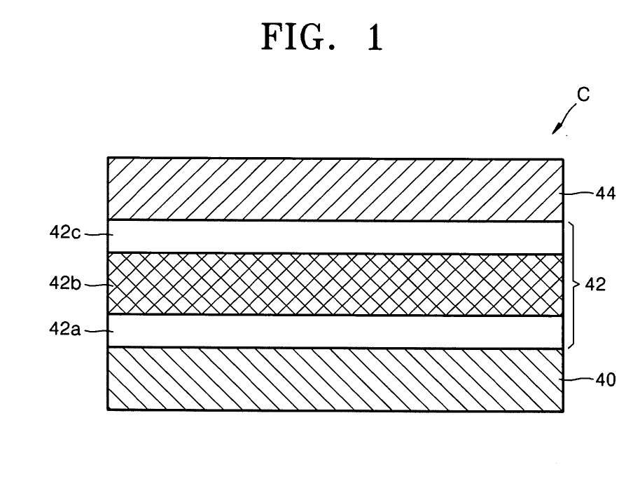

FIG. 1 illustrates a cross-sectional view of a nonvolatile capacitor of a semiconductor device according to an embodiment of the present invention.

Referring to FIG. 1, a nonvolatile capacitor C of a semiconductor device according to an embodiment of the present invention includes a lower electrode 40, a dielectric layer 42, and an upper electrode 44. The lower electrode 40 may be a platinum electrode. The upper electrode 44 may be a ruthenium electrode. Thus, the lower electrode 40 and the upper electrode 44 may be made of different materials. Generally, the type of dielectric layer 42 used determines the materials of the lower and upper electrodes 40 and 44.

The dielectric layer 42 includes a first insulating layer 42a, a phase-transition layer 42b stacked on the first insulating layer 42a, and a second insulating layer 42c stacked on the phase-transition layer 42b. Although not illustrated, another material layer may be interposed between the lower electrode 40 and the first insulating layer 42a. Similarly, another material layer may be interposed between the second insulating layer 42c and the upper electrode 44. The first insulating layer 42a is a dielectric layer having a predetermined thickness and dielectric constant. For example, the first insulating layer 42a may be a silicon oxide layer, a tantalum oxide layer, or an aluminum oxide layer. The second insulating layer 42c is preferably identical to the first insulating layer 42a, but may be a dielectric layer different from the first insulating layer 42a.

In the capacitor C shown in FIG. 1, a first voltage may be applied to the first insulating layer 42a or a second voltage may be applied to the second insulating layer 42c. A third voltage may be applied to the phase-transition layer 42b. Preferably, the third voltage, which may be applied to the phase-transition layer 42b is equal to or greater than the first voltage, which may be applied to the first insulating layer 42a or the second voltage, which may be applied to the second insulating layer 42c.

A voltage applied to each component of the capacitor C is inversely proportional to the capacitance of the component. Accordingly, to make the third voltage equal to or greater than the first and second voltages, the capacitances of the first insulating layer 42a and the second insulating layer 42c must be equal to or greater than the capacitance of the phase-transition layer 42b.

When thicknesses and facing areas of the first and second insulating layers 42a and 42c, and the phase-transition layer 42b are equal, the phase-transition layer 42b is preferably a dielectric layer having a dielectric constant less than a dielectric constant of the first and second insulating layers 42a and 42c. For example, the phase-transition layer 42b may be a niobium oxide layer (Nb₂O₅) having a predetermined thickness.

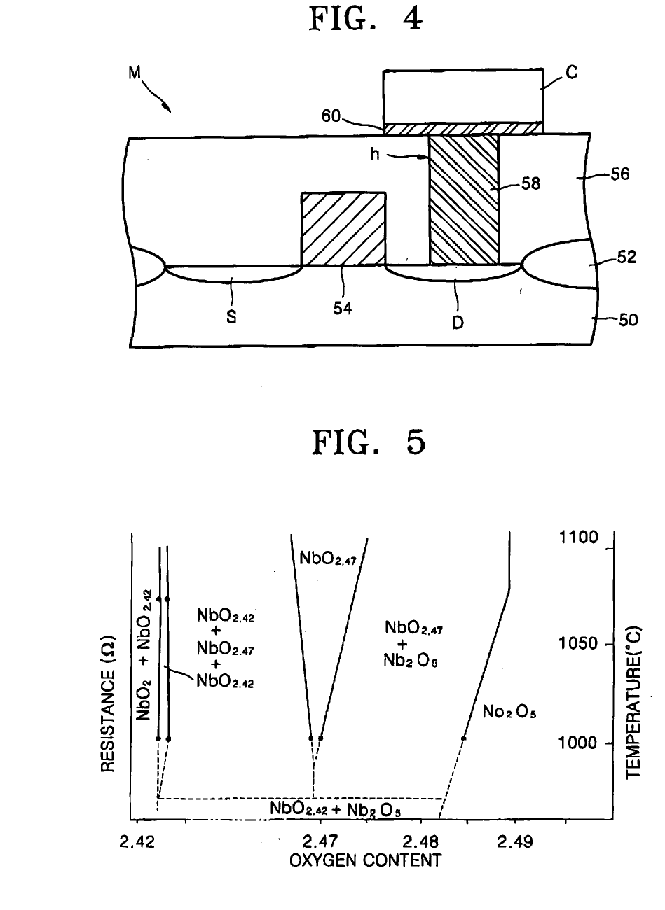

FIG. 5 is a plot illustrating various phases of a niobium oxide layer according to a content of oxygen. When the phase-transition layer 42b is a niobium oxide layer showing various phases according to the content of oxygen, electrons are injected to the phase-transition layer 42b such that at least one oxygen atom of the niobium oxide layer is separated and the insulating property of the phase-transition layer 42b is changed. The first and second insulating layers 42a and 42c prevent the separated oxygen atom from being discharged out of the phase-transition layer 42b.

FIG. 2 is a graph of current versus voltage illustrating operational characteristics of the capacitor of FIG. 1.

More specifically, FIG. 2 is a graph illustrating resistance characteristics of a capacitor (referred to as a “to-be-tested capacitor”) including a platinum electrode as the lower electrode 40, a ruthenium electrode as the upper electrode 44, a tantalum oxide layer having a thickness of 50 Å as the first insulating layer 42a, a niobium oxide layer having a thickness of 60 Å as the phase-transition layer 42b, and a tantalum oxide layer having a thickness of 50 Å as the second insulating layer 42c.

Symbols Δ and ⋄ in the graph of FIG. 2 represent a current change of the to-be-tested capacitor when a voltage is applied to the to-be-tested capacitor after the insulating property of the phase-transition layer 42b has been destroyed. That is, symbols Δ and ⋄ represent a resistance change of the to-be-tested capacitor.

Referring to symbols Δ and ⋄ in the graph of FIG. 2, a current of the to-be-tested capacitor measured when the voltage is applied to the to-be-tested capacitor with the phase-transition layer 42b, the insulating property thereof having been destroyed, is approximately 10⁻² A. However, as the voltage applied to the to-be-tested capacitor exceeds a predetermined value, for example, 2 V, the current of the to-be-tested capacitor significantly decreases to approximately 10⁻¹¹ A. This means that the resistance of the to-be-tested capacitor significantly increases. Further, although a high voltage is applied to the capacitor after the current of the to-be-tested capacitor decreases to approximately 10⁻¹¹ A, the current of the to-be-tested capacitor does not significantly increase.

Hereinafter, the to-be-tested capacitor with the phase-transition layer 42b, the insulating property thereof having been destroyed, is referred to as a first state capacitor. A first voltage is a voltage measured when a relatively high current, e.g., 10⁻² A, is measured in the first state capacitor. A second voltage is a voltage measured when a relatively low current, e.g., 10⁻¹¹ A, is measured in the first state capacitor.

Symbols ∇ and ◯ in the graph of FIG. 2 represent a current change of the first state capacitor when the current of the first state capacitor is significantly lowered by applying the second voltage to the first state capacitor and then applying the first voltage to the first state capacitor.

Referring to symbols ∇ and ◯ in the graph of FIG. 2, although the first voltage is applied to the first state capacitor after the current of the first state capacitor is significantly lowered by applying the second voltage to the first state capacitor, the current of the first state capacitor does not increase. This means that after the resistance of the first state capacitor is increased by applying the second voltage to the first state capacitor, although any voltage is applied to the first state capacitor, the high resistance of the first state capacitor is maintained.

Data can be stored in a nonvolatile state in the capacitor C having such current characteristics, i.e., resistance characteristics. For example, if the current of the first state capacitor is high, i.e., the resistance of the first state capacitor is low, it may be considered that an arbitrary data, e.g., a bit data 1 , is written. Alternatively, if the resistance of the first state capacitor is high, it may be considered that another arbitrary data, e.g., a bit data 0, is written.

In the latter case, as described above, since the low resistance state is maintained irrespective of the existence of the applied voltage once the resistance of the first state capacitor decreases, the bit data 0 stored in the capacitor C is not lost regardless of whether is the applied voltage is interrupted.

The endurance of the to-be-tested capacitor was tested. The endurance test consisted of making the to-be-tested capacitor become the first state capacitor, decreasing or increasing the resistance of the first state capacitor, and measuring the current of the first state capacitor. The endurance test was repeatedly performed many times.

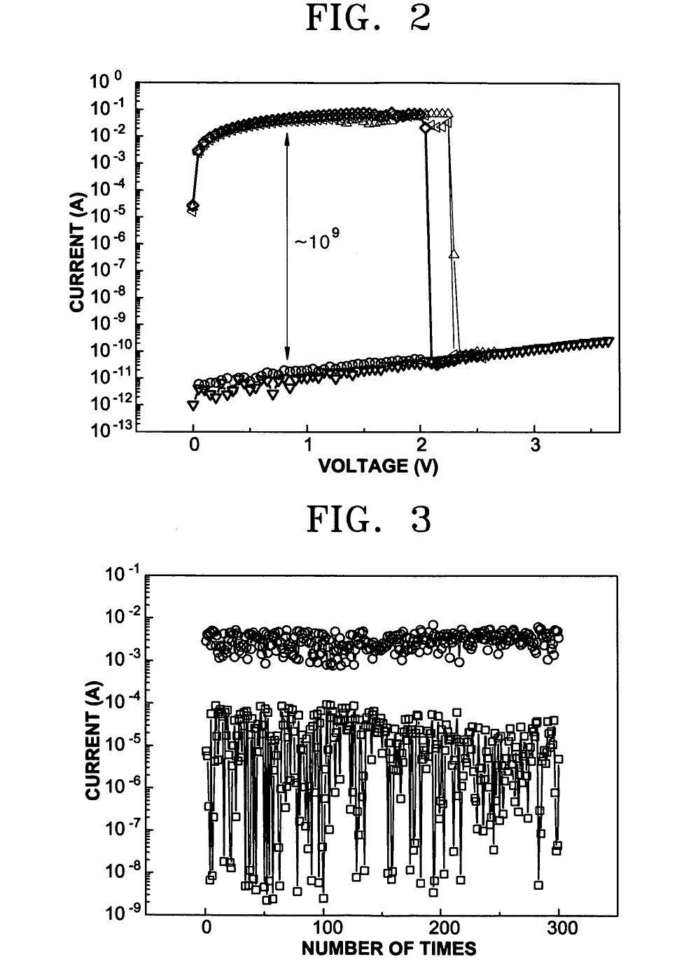

FIG. 3 is a graph of current versus a number of times the endurance test was performed illustrating results of the endurance test of the capacitor of FIG. 1. Symbol □ in FIG. 3 represents a first current measured when the resistance of the first state capacitor is low; symbol ◯ in FIG. 3 represents a second current measured when the resistance of the first state capacitor is high.

Referring to FIG. 3, while the first current and the second current vary whenever they are measured, it may be seen that the second current is more than ten times greater than the first current.

These results indicate that the endurance of the capacitor according to the present invention is excellent. Since the second current is more than ten times greater than the first current, as seen throughout the endurance test results, whether the measured current of the to-be-tested capacitor is the first current or the second current is clearly identifiable. Accordingly, data stored in the capacitor of the present invention can be read correctly even after passage of a significant length of time.

FIG. 4 illustrates a cross-sectional view of a semiconductor memory device according to an embodiment of the present invention, the semiconductor memory device including the capacitor of FIG. 1.

A semiconductor memory device M including the capacitor C of FIG. 1 will now be explained with reference to FIG. 4.

Referring to FIG. 4, field oxide layers 52 are formed on predetermined areas of a substrate 50. A transistor, e.g., a gate 54, is formed on the substrate 50 between the field oxide layers 52. A source region S and a drain region D are formed on the substrate 50 between the gate 54 and one of the field oxide layers 52 and between the gate 54 and another one of the field oxide layers 52, respectively. The source region S and the drain region D may be formed through implantation of conductive impurities. An interlayer insulating layer 56, e.g., a boron-phosphorous-silicate glass (BPSG) layer, is formed on the substrate 50 to cover the field oxide layers 52 and the transistor. A contact hole h is formed through the interlayer insulating layer 56 to expose the drain region D. The contact hole h. is then filled with a conductive plug 58. A diffusion barrier 60 may be formed on the interlayer insulating layer 56 to cover the conductive plug 58. The capacitor C is then formed on the diffusion barrier 60. The capacitor C preferably includes the lower electrode 40, the dielectric layer 42, and the upper electrode 44 as described in connection with FIG. 1.

When a particular lower electrode 40 and dielectric layer 42 are selected or when the lower electrode 40 itself is able prevent carriers from being diffused into the conductive plug 58 from the capacitor C, the diffusion barrier 60 may be omitted.

It is preferable that a surface area of the capacitor C is large. Accordingly, the capacitor may not be a simple stacked capacitor, but may be a more complex three-dimensional capacitor, such as a cylinder-type stacked capacitor.

A method of manufacturing the above-described semiconductor memory device M may include conventionally forming the transistor on the substrate 50, forming the interlayer insulating layer 56 on the substrate 50 to cover the transistor, forming the contact hole h through the interlayer insulating layer 56 to expose the drain region D of the transistor, filling the contact hole h with the conductive plug 58, and forming the capacitor C on the interlayer insulating layer 56 to contact the conductive plug 58. The diffusion barrier 60 may be formed between the conductive plug 58 and the capacitor C.

As shown in FIG. 1, the capacitor C may be formed by forming the lower electrode 40, stacking the dielectric layer 42, which includes the first insulating layer 42a, the phase-transition layer 42b, and the second insulating layer 42c, on the lower electrode 40, and stacking the upper electrode 44 on the dielectric layer 42. The first insulating layer 42a may be a dielectric layer, e.g., a silicon oxide layer, a tantalum oxide layer, or an aluminum oxide layer, having a first thickness. The second insulating layer 42c may be a dielectric layer, e.g., a silicon oxide layer, a tantalum layer, or an aluminum layer, having a second thickness. The phase-transition layer 42b may be a dielectric layer having a third thickness that is capable of exhibiting different resistance characteristics according to a range of applied voltages depending on whether the insulating property thereof has been destroyed, e.g., by electrons being injected thereinto. For example, the phase-transition layer 42b may be an oxide layer of Group 5 atoms. A niobium layer is preferably used as the oxide layer of Group 5 atoms, but another oxide layer may alternatively be used. The first, second, and third thicknesses can be the same, but it is preferable that a ratio of the first, second, and third thicknesses is 5:6:5. For example, when both the lower electrode 42 and the upper electrode 44 have a thickness of 50 Å, the phase-transition layer 42b may have a thickness of 60 Å.

The electrons used to cause a phase transition of the phase-transition layer 42b, that is, used to cause the phase-transition layer 42b to display different resistance characteristics in different voltage ranges, may be injected to the phase-transition layer 42b by applying a predetermined voltage to the capacitor C. The predetermined voltage applied to the capacitor C is a voltage at which the insulating property of the phase-transition layer 42b is changed or destroyed. In this process, it is preferable that a voltage across the phase-transition layer 42b is equal to or greater than a voltage across the first and second insulating layers 42 and 44. Accordingly, it is preferable that the phase-transition layer 42b has a dielectric constant less than the dielectric constants of the dielectric layers used as the first and second insulating layers 42 and 44.

Alternatively, the electrons used to destroy the insulating property of the phase-transition layer 42b can be injected into the phase-transition layer 42b by externally applying electrons having an energy that is high enough to pass through the upper electrode 44 and reach the phase-transition layer 42b to the capacitor C, instead of applying the predetermined voltage to the capacitor C. Alternatively, if the phase-transition layer 42b is a niobium oxide layer, the insulating property of the phase-transition layer 42b can also be destroyed by applying light to the capacitor C. The light, e.g., ultraviolet light, should have an energy that is high enough to separate some components, i.e., at least one oxygen, of the phase-transition layer. The first and second insulating layers 42a and 42c prevent the separated oxygen from being discharged out of the phase-transition layer 42b.

A method of operating the semiconductor memory device M shown in FIG. 4 will now be explained.

<Write>

First, a voltage capable of destroying the insulating property of the dielectric layer of the capacitor C is applied to the capacitor C to destroy the insulating property of the dielectric layer. As the insulating property of the dielectric layer is destroyed, the capacitor C becomes the first state capacitor having the resistance characteristics as described above with reference to FIG. 2.

If the first voltage is applied to the first state capacitor, the resistance of the first state capacitor is lowered. If the second voltage is applied to the first state capacitor, the resistance of the first state capacitor is increased.

Hence, after the insulating property of the dielectric layer is destroyed and the transistor is turned on, the bit data 1 can be written by applying the first voltage to the first state capacitor, or the bit data 0 can be written by applying the second voltage to the first state capacitor. Alternatively, the written bit data values may be reversed.

<Read>

When an arbitrary bit data is written to the semiconductor memory device M of FIG. 4, the resistance of the phase-transition layer 42 varies according to the written bit data. Accordingly, the transistor is turned on, and the current of the capacitor is measured by applying a predetermined read voltage to the capacitor. If the measured current value is greater than a reference value, it is determined that the bit data 1 is read from the semiconductor memory device M. If the measured current value is less than the reference value, it is determined that the bit data 0 is read from the semiconductor memory device M. As noted above, the bit data according to the measured current values may be reversed, i.e., bit data 1 may be bit data 0, and bit data 0 may be bit data 1.

As described above, the dielectric layer of the capacitor according to the present invention includes the phase-transition layer capable of exhibiting two phases such that the phase-transition layer displays different resistance characteristics according to the range of applied voltages and maintains the characteristics irrespective of the existence of the applied voltage after the insulating property thereof is changed or destroyed, e.g., by injected electrons. A capacitor according to an embodiment of the present invention can be easily manufactured using a conventional semiconductor manufacturing process, and, thus, an additional process is not needed. Consequently, when the capacitor of the present invention is applied to a general nonvolatile semiconductor memory device, such as a DRAM, the semiconductor memory device can maintain its original operation speed and advantageously possess nonvolatile characteristics. That is, the semiconductor memory device including the capacitor according to the present invention can have advantages of both DRAM and flash memory.

Exemplary embodiments of the present invention have been disclosed herein and, although specific terms are employed, they are used and are to be interpreted in a generic and descriptive sense only and not for purpose of limitation. For example, the transistor may be a thin film transistor, and some of the layers constituting the dielectric layer 42 may be ferroelectric layers. Moreover, a semiconductor memory device other than the semiconductor memory device shown in FIG. 4 may include the capacitor shown in FIG. 1. Accordingly, it will be understood by those of ordinary skill in the art that various changes in form and details may be made without departing from the spirit and scope of the present invention as set forth in the following claims.

1. A capacitor of a semiconductor device, the capacitor comprising:
a lower electrode;
a dielectric layer stacked on the lower electrode, the dielectric layer including a phase-transition layer capable of exhibiting two different resistance characteristics depending on whether an insulating property thereof has been changed; and
an upper electrode stacked on the dielectric layer.

2. The capacitor as claimed in claim 1, wherein the dielectric layer comprises:
a first insulating layer stacked on the lower electrode;
the phase-transition layer stacked on the first insulating layer; and
a second insulating layer stacked on the phase-transition layer.

3. The capacitor as claimed in claim 2, wherein the first insulating layer is a dielectric layer having a dielectric constant greater than a dielectric constant of the phase-transition layer.

4. The capacitor as claimed in claim 3, wherein the dielectric layer is one selected from the group consisting of a silicon oxide layer, a tantalum oxide layer and an aluminum oxide layer.

5. The capacitor as claimed in claim 2, wherein the second insulating layer is a dielectric layer having a dielectric constant greater than a dielectric constant of the phase-transition layer.

6. The capacitor as claimed in claim 5, wherein the dielectric layer is one selected from the group consisting of a silicon oxide layer, a tantalum oxide layer, and an aluminum oxide layer.

7. The capacitor as claimed in claim 2, wherein a thickness ratio of the first insulating layer, the phase-transition layer, and the second insulating layer is 5:6:5.

8. The capacitor as claimed in claim 2, wherein at least one of the layers constituting the dielectric layer is a ferroelectric layer.

9. The capacitor as claimed in claim 1, wherein the phase-transition layer is a dielectric layer capable of exhibiting two different resistance characteristics according to an applied voltage after at least one component of the phase-transition layer is separated by electrons injected into the phase-transition layer.

10. The capacitor as claimed in claim 9, wherein the dielectric layer is a niobium oxide layer.

11. The capacitor as claimed in claim 1, wherein the phase-transition layer is a dielectric layer capable of exhibiting two different resistance characteristics according to an applied voltage after at least one component of the phase-transition layer is separated by light applied to the capacitor.

12. The capacitor as claimed in claim 1, wherein the capacitor is a cylinder-type stacked capacitor.

13. A semiconductor memory device including a transistor and a capacitor, the capacitor comprising:
a lower electrode;
a dielectric layer stacked on the lower electrode, the dielectric layer including a phase-transition layer capable of displaying two different resistance characteristics depending on whether an insulating property thereof has been changed; and
an upper electrode stacked on the dielectric layer.

14. The semiconductor memory device as claimed in claim 13, wherein the dielectric layer comprises:
a first insulating layer stacked on the lower electrode;
the phase-transition layer stacked on the first insulating layer; and
a second insulating layer stacked on the phase-transition layer.

15. The semiconductor memory device as claimed in claim 14, wherein the first insulating layer is a dielectric layer having a dielectric constant greater than a dielectric constant of the phase-transition layer.

16. The semiconductor memory device as claimed in claim 15, wherein the dielectric layer is one selected from the group consisting of a silicon oxide layer, a tantalum oxide layer, and an aluminum oxide layer.

17. The semiconductor memory device as claimed in claim 14, wherein the second insulating layer is a dielectric layer with a dielectric constant greater than a dielectric constant of the phase-transition layer.

18. The semiconductor memory device as claimed in claim 17, wherein the dielectric layer is one selected from the group consisting of a silicon oxide layer, a tantalum oxide layer, or an aluminum oxide layer.

19. The semiconductor memory device as claimed in claim 14, wherein the phase-transition layer is a dielectric layer capable of exhibiting two different resistance characteristics according to a range of an applied voltage after at least one component of the phase-transition layer is separated by electrons injected into the phase-transition layer.

20. The semiconductor memory device as claimed in claim 14, wherein a thickness ratio of the first insulating layer, the phase-transition layer, and the second insulating layer is 5:6:5.

21. The semiconductor memory device as claimed in claim 14, wherein at least one of the layers constituting the dielectric layer is a ferroelectric layer.

22. The semiconductor memory device as claimed in claim 13, wherein the phase-transition layer is a dielectric layer capable of exhibiting two different resistance characteristics according to a range of an applied voltage after at least one component of the phase-transition layer is separated by electrons injected into the phase-transition layer.

23. The semiconductor memory device as claimed in claim 22, wherein the dielectric layer is a niobium oxide layer.

24. The capacitor as claimed in claim 13, wherein the phase-transition layer is a dielectric layer capable of exhibiting two different resistance characteristics according to an applied voltage after at least one component of the phase-transition layer is separated by light applied to the capacitor.

25. The semiconductor memory device as claimed in claim 13, wherein the capacitor is a cylinder-type stacked capacitor.

26. A method of operating a semiconductor memory device including a transistor and a capacitor, wherein the capacitor includes a lower electrode, a dielectric layer including a phase-transition layer capable of exhibiting two different resistance characteristics depending on whether an insulating property thereof has been changed, and an upper electrode, the method comprising:
changing the insulating property of the phase-transition layer; and
applying a write voltage to the capacitor while leaving the transistor turned on.

27. The method as claimed in claim 26, wherein changing the insulating property of the phase-transition layer comprises injecting electrons into the phase-transition layer.

28. The method as claimed in claim 27, wherein injecting electrons into the phase-transition layer comprises applying a voltage to the capacitor.

29. The method as claimed in claim 26, wherein changing the insulating property of the phase-transition layer comprises applying light to the capacitor.

30. The method as claimed in claim 29, wherein the light is ultraviolet light.

31. A method of operating a semiconductor memory device including a transistor and a capacitor, wherein the capacitor includes a lower electrode, a dielectric layer including a phase-transition layer capable of exhibiting two different resistance characteristics depending on whether an insulating property thereof has been changed, and an upper electrode, the method comprising:
measuring a current by applying a read voltage to the capacitor while leaving the transistor turned on; and
comparing the measured current value with a reference value.
